(19) United States
(12) Patent Application Publication
(10) Pub. No.: US 2026/0150200 A1
(43) Pub. Date: May 28, 2026

(54) QUICK RELEASE HOUSING SYSTEM FOR AUTOMOTIVE ELECTRIC MODULES

(71) Applicant: GM GLOBAL TECHNOLOGY OPERATIONS LLC, Detroit, MI (US)

(72) Inventor: Ricardo Pineda Sanchez, Zinacantepec (MX)

(73) Assignee: GM GLOBAL TECHNOLOGY OPERATIONS LLC, Detroit, MI (US)

(21) Appl. No.: 18/956,749

(22) Filed: Nov. 22, 2024

(51) Int. Cl. H05K 5/00; H05K 5/02

(52) U.S. Cl. CPC H05K 5/0052; H05K 5/0073; H05K 5/0221

(57) ABSTRACT

A quick release housing system includes an electric module and a housing receiving the electric module in a latched state. The housing is capable of moving to an unlatched state to release the electric module for removal. The electric module includes catches and the housing includes latch arms that engage the catches in the latched state. The housing includes at least one actuator moveable to simultaneously disengage the latch arms from the catches in the unlatched state.

### INTRODUCTION

The technical field generally relates to electric modules and assemblies used in electrical systems, and more particularly relates to quick release housings for electric modules such as switch modules in a vehicle door.

Electrical systems, which often contain or include electronics, are used in most manufactured products. Electric power is communicated through these systems, usually via conductors such as wires, tapes, rails, foils, etc. The conductors may be arranged in circuits and/or networks. Various electrical components may be interconnected in the circuits/networks to effect a variety of functions related to the distribution, conditioning and/or control of power. Some electrical components may be in the form of a box, a board, a module, or another construction. The electrical components may be held in place on or in the product by fasteners, clips, coupling features, ties or other means of securement. The electrical components may be factory prewired or connected in the field via connectors such as plugs for attachment into intercoupled connectors, such as in sockets.

Many electrical components are assembled in their respective product in a manner that enables their removal for testing, service, repair or replacement. Electrical connectors often have releasable locking features to facilitate connection and disconnection. Other electrical components such as modules may be more difficult to remove. It would be desirable if electric components were more readily removed from their product when needed.

Accordingly, there is an ongoing desire for electrical systems and parts thereof to be provided with readily removeable components, including for serviceability purposes. Furthermore, other desirable features and characteristics of the present disclosure will become apparent from the subsequent detailed description and the appended claims, taken in conjunction with the accompanying drawings and the foregoing introduction.

### SUMMARY

A quick release housing system is provided for products with electrical systems. In a number of embodiments, A quick release housing system includes an electric module and includes a housing receiving the electric module in a latched state. The housing is capable of moving to an unlatched state to release the electric module for removal. The electric module includes any number of catches and the housing includes any number of latch arms that engage the catches in the latched state. The housing includes at least one actuator moveable to simultaneously disengage the latch arms from the catches to effect the unlatched state.

In additional embodiments, the actuator includes a tab suspended from the housing by a pair of actuator links so that the tab is moveable toward the electric module to disengage the number of latch arms.

In additional embodiments, two actuators are included with one at each end of the electric module.

In additional embodiments, the housing includes a bezel encircling the electric module and the latch arms are supported on the bezel in a cantilevered manner.

In additional embodiments, the electric module has a guide and the housing has a receiver with a tapered entry for receiving the guide to direct the electric module into the housing.

In additional embodiments, the electric module has a stop and the housing has a receiver for receiving the stop to limit movement of the electric module into the housing.

In additional embodiments, each latch arm has a free end and another end connected to the actuator.

In additional embodiments, a bezel is included in the housing. The electric module has a control panel that extends into the bezel and that includes switches.

In additional embodiments, the electric module is disposed in the armrest.

In additional embodiments, the housing includes four latch arms, each latch arm engaged with two catches of the electric module in the latched state.

In a number of additional embodiments, a quick release housing system includes an electric module having a first end and a second end disposed opposite the first end. A housing receives the electric module in a latched state and is moveable to an unlatched state to release the electric module for removal. The electric module includes a plural number of catches. The housing includes a number of latch arms that engage the catches in the latched state. The housing includes a actuators at ends of the electric module. The actuators are moveable to simultaneously disengage the latch arms from the catches in the unlatched state.

In additional embodiments, the actuators each include a tab suspended from the housing by a pair of actuator links so that the tabs are moveable toward the electric module to disengage the latch arms.

In additional embodiments, the actuators each includes a tab. The tabs are moveable toward one another to move the housing to the unlatched state.

In additional embodiments, the housing includes a bezel encircling the electric module, where each of the number of latch arms is connected with the bezel by three supports in a cantilevered manner.

In additional embodiments, the electric module has a plural number of guides, and the housing has a corresponding number of receivers, each with a tapered entry for receiving one of the guides to direct the electric module into the housing.

In additional embodiments, the electric module has a stop shaped as an elongated boss projecting from the electric module, and the housing has a receiver for receiving the stop to limit movement of the electric module into the housing.

In additional embodiments, each latch arm has a free end and another end connected to one of the actuators, where the housing includes four latch arms, each latch arm engaged with two catches of the electric module in the latched state.

In additional embodiments, a bezel is included in the housing, where the electric module has a control panel that extends into the bezel and that includes switches, and the electric module is connected in an electrical circuit.

In additional embodiments, the electric module is disposed in the armrest, and the housing has a flange clipped onto the armrest.

In a number of other embodiments, a quick release housing system for an electrical system of a vehicle includes an electric module with a control panel. A housing receives the electric module in a latched state and is moveable to an unlatched state to release the electric module for removal. The housing is connected to the vehicle. The electric module includes catches, each catch having a surface disposed substantially parallel to the bottom of the electric module and facing the bottom. The housing includes a number of latch arms that engage the catches at the surfaces in the latched state. The housing includes an actuator or actuators at ends of the electric module. The actuator(s) are moveable to simultaneously disengage the latch arms from the surfaces of the catches in the unlatched state.

### BRIEF DESCRIPTION OF THE DRAWINGS

The exemplary embodiments will hereinafter be described in conjunction with the following drawing figures, wherein like numerals denote like elements, and wherein:

FIG. 1 is a functional block diagram of a vehicle including a quick release electric module housing system, in accordance with various embodiments;

FIG. 2 is an interior view of door of the vehicle of FIG. 1 with an electric module, in accordance with various embodiments;

FIG. 3 is a perspective view of the electric module of FIG. 2 in its housing and shown removed from the door, in accordance with various embodiments;

FIG. 4 is a perspective view of the housing of FIG. 3 and shown in isolation with the module removed, in accordance with various embodiments;

FIG. 5 is a perspective view of the housing and parts of the module of FIG. 3, in accordance with various embodiments;

FIG. 6 is a fragmentary, plan view of part of the electric module and housing of FIG. 3 with a quick release feature in a latched state, in accordance with various embodiments;

FIG. 7 is a schematic, sectional illustration of the latch point area of the electric module and housing of FIG. 3 in the latched state, in accordance with various embodiments;

FIG. 8 is a fragmentary, plan view of part of the electric module and housing of FIG. 3 with the quick release feature in an unlatched state, in accordance with various embodiments; and

FIG. 9 is a schematic, sectional illustration of the latch point area of the electric module and housing of FIG. 3 in the unlatched state, in accordance with various embodiments.

### DETAILED DESCRIPTION

The following detailed description is merely exemplary in nature and is not intended to limit the application and uses. Furthermore, there is no intention to be bound by any expressed or implied theory presented in the preceding introduction or the following detailed description.

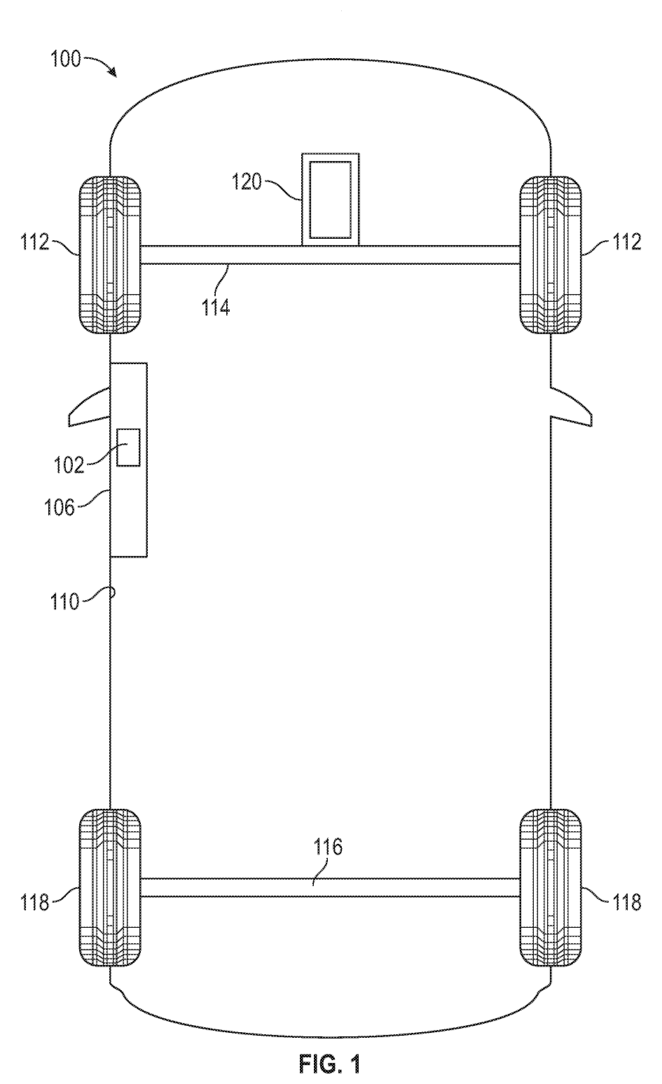

FIG. 1 illustrates a vehicle 100, according to an exemplary embodiment. As described in greater detail further below, the vehicle 100 includes a quick release housing system 102 that is installed in a door assembly 106 but may be used at any location in the vehicle 100 including with engine compartment, underbody and interior components. As described in greater detail below, the quick release housing system102 is installed during assembly of a body 110 of the vehicle 100.

In certain embodiments, the vehicle 100 includes a front axle 114 and a rear axle 116. In some embodiments, the vehicle 100 comprises an automobile. In various embodiments, the vehicle 100 may be any one of a number of different types of automobiles, such as, for example, a sedan, a wagon, a truck, or a sport utility vehicle (SUV), and may be two-wheel drive (2WD) (i.e., rear-wheel drive or front-wheel drive), four-wheel drive (4WD) or all-wheel drive (AWD), and/or various other types of vehicles in certain embodiments. In certain embodiments, the vehicle 100 may also comprise one or more other types of vehicles. In addition, in various embodiments, it will also be appreciated that the vehicle 100 may comprise any number of other types of mobile platforms.

In the depicted embodiment, the body 110 of the vehicle 100 substantially encloses other components of the vehicle 100. Also in the depicted embodiment, the vehicle 100 includes the above-referenced axles 114, 116 and front wheels 112, as well as rear wheels 118. The wheels 112, 118 are each rotationally coupled to a respective one or more of the axles 114, 116 near a respective corner of the body 110 to facilitate movement of the vehicle 100. In one embodiment, the vehicle 100 includes four wheels 112, 118 (namely, two front wheels 112 and two rear wheels 118), although this may vary in other embodiments (for example for trucks and certain other vehicles).

In various embodiments, a drive system 120 drives the wheels 112, 113. The drive system 120 preferably comprises a propulsion system. In certain exemplary embodiments, the drive system 120 comprises an internal combustion engine and/or an electric motor/generator. In certain embodiments, the drive system 120 may vary, and/or two or more drive systems 120 may be used. By way of example, the vehicle 100 may also incorporate any one of, or combination of, a number of different types of propulsion systems, such as, for example, a gasoline or diesel fueled combustion engine, a “flex fuel vehicle” (FFV) engine (i.e., using a mixture of gasoline and alcohol), a gaseous compound (e.g., hydrogen and/or natural gas) fueled engine, a combustion/electric motor hybrid engine, and an electric motor.

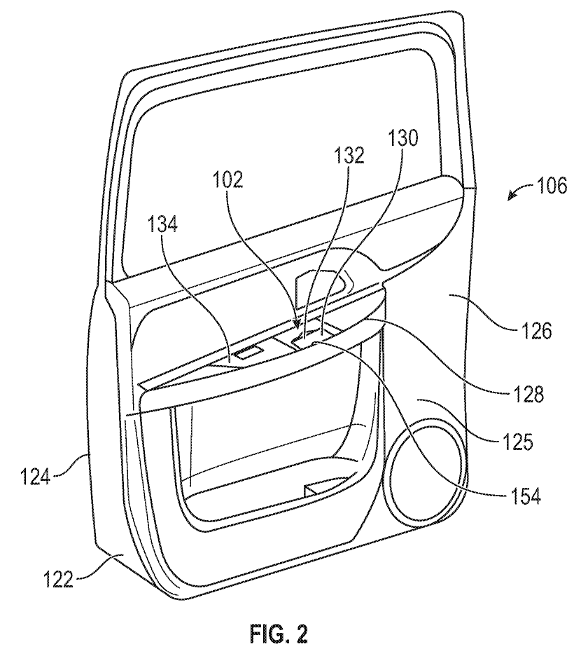

Referring to FIG. 2, the door 106 includes a structure 122 with an exterior panel 124, such as made of formed sheet metal or plastic. The door 106 includes a trim panel 125 on its interior side 126. Between the exterior panel 124 and the trim panel 125 a hollow interior (not shown) is defined within which components may be routed or housed. The interior side 126 of the door 106 may include various features such as an armrest 128. The quick release housing system 102 includes a module 130 with a control panel 132 that is exposed on/at a surface 134 the armrest 128. In the current embodiment, the control panel 132 includes various controls such as to control windows, door locks, mirrors, etc. In other embodiments, the quick release housing system 102 including the module 130 may perform functions that allow it to be contained within the door 106 and not visible/accessible without disassembly of the door 106 such as by removing the trim panel 125. In additional embodiments, the quick release housing system 102 including the module 130 may be located at a different location of the vehicle 100 or in another product. The module 130 as a container for electrical components may also be referred to as a box.

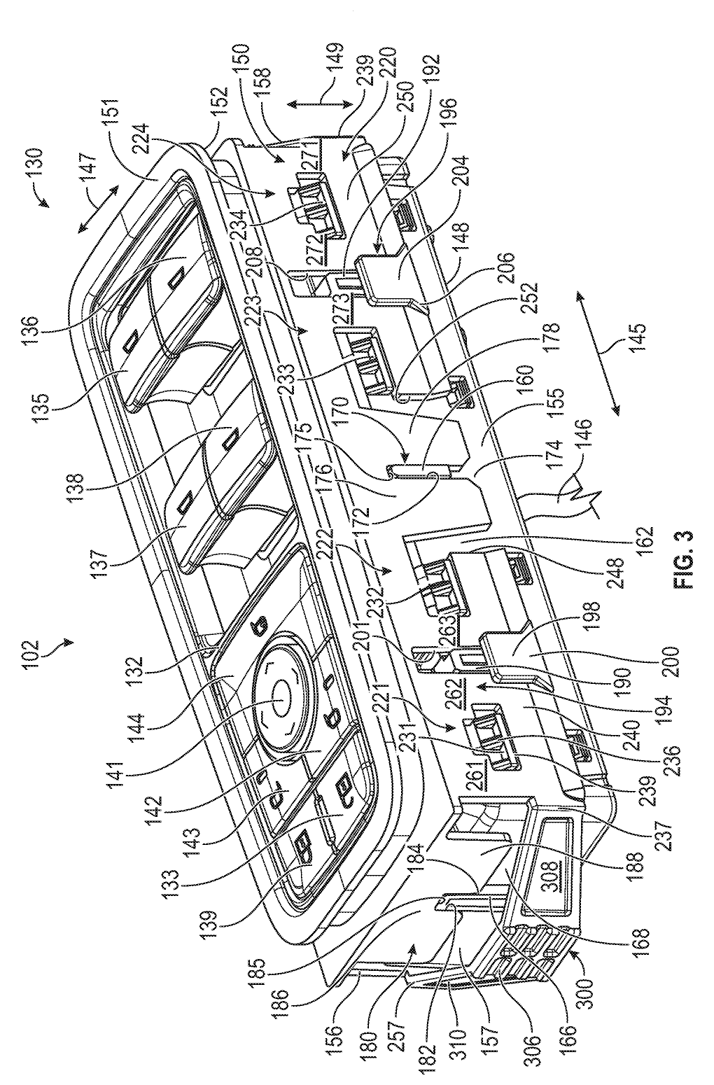

Referring to FIG. 3, parts of the quick release housing system 102 including the module 130 are shown. In this embodiment the module 130 is a switch module 130 and includes the control panel 132. The control panel 132 includes window switches 135-138 to control windows of the vehicle 100, four mirror switches 141-144 to control outside rearview mirrors, and two lock switches 133 and 139 to control locks such as of the door 106. Various wires 146 are connected to the bottom 148 of the module 130 by releasable connectors (not shown) to communicate with a power supply and the controlled features.

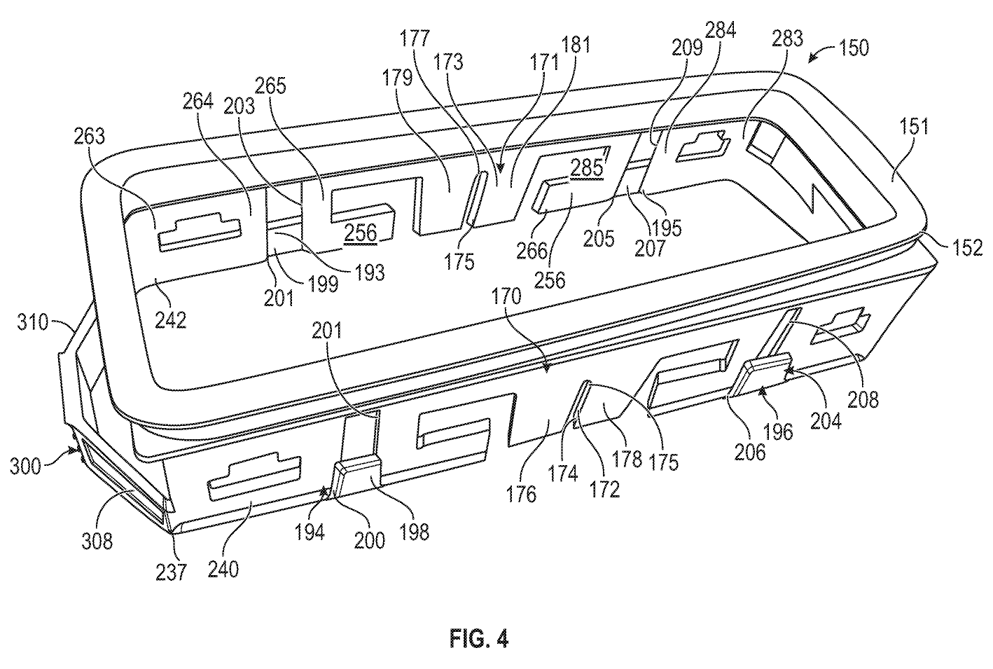

FIG. 3 shows the module 130 is coupled with a housing 150. Referring additionally to FIG. 4, the housing 150 is shown in isolation. The housing 150 includes a ring referred to as a bezel 151 that surrounds the control panel 132 and provides structural integrity for the housing 150. The bezel 151 has a flange 152 for clipping into an opening 154 of the armrest 128 (FIG. 2) to present the control panel 132 in an accessible disposition. The module 130 has a length in the longitudinal direction 145, a width in the lateral direction 147 and a height in the transverse direction 149. The module 130 has side walls 155 and 156 and has end walls 157 and 158 and is generally constructed in the shape of a rectangular block. The side walls 155 and 156 extend in the longitudinal direction 145 and the end walls 157 and 158 extend in the lateral direction 147. Both the side walls 155 and 156 and the end walls 157 and 158 also extend between the bottom 148 and the control panel 132 in the transverse direction 149.

The side walls 155 and 156 each have a stop 160 for insertion of the module 130 into the housing 150. The stop 160 on the side wall 155 is visible and the stop 160 on the side wall 156 (behind the module 130 as viewed) is substantially the same. The stop 160 is formed as an elongated, linear boss projecting from its surrounding surface 162 of the side wall 155. The stop 160 is centered on the side wall 155 between the end walls 157 and 158 and extends parallel to the end walls 157 and 158 partially between the control panel 132 and the bottom 148. The stop (not visible) on the side wall 156 is similar to the stop 160.

The end walls 157-158 also each have a stop, with the stop 166 on the end wall 157 visible in FIG. 3. The stop 166 is formed as an elongated, linear boss projecting from its surrounding surface 168 of the end wall 157. The stop 166 is centered on the end wall 157 between the side walls 155 and 156 and extends parallel to the side walls 155 and 156 partially between the control panel 132 and the bottom 148. The stop (not visible) on the end wall 158 is similar to the stop 160.

Referring additionally to FIG. 4, the housing 150 has a receiver 170 with a slot 172 that has an open end 174 that receives the stop 160 when the module 130 and the housing 150 are connected and a blind end 175 that contacts the stop 160 when the module 130 is fully inserted into the housing 150. The receiver 170 has a pair of arms 176 and 178 that extend from the bezel 151 and away from the flange 152, with one of the arms 176 and 178 on each side of the stop 160.

A similar receiver 171 (FIG. 4) is included on the opposite side of the housing 150 at the side wall 156 of the module 130. That receiver 171 includes a slot 173 that has an open end 175 to receive its respective stop on the side wall 156 when the module 130 and the housing 150 are connected and a blind end 177 that contacts the respective stop when the module 130 is fully inserted into the housing 150. The receiver 171 has a pair of arms 179 and 181 that extend from the bezel 151 and away from the flange 152, with one of the arms 179 and 181 on each side of the respective stop.

The housing 150 has a receiver 180 with a slot 182 that has an open end 184 that receives the stop 166 on the end wall 157 when the module 130 and the housing 150 are connected and a blind end 185 that contacts the stop 166 when the module 130 is fully inserted into the housing 150. The receiver 180 has a pair of arms 186 and 188 that extend from the bezel 151 and away from the flange 152, with one of the arms 186 and 188 on each side of the stop 166. A similar receiver is included on the opposite side of the housing 150 at the end wall 158 of the module 130. The four stops, including the stops 160 and 166 prevent over-insertion of the module 130 into the housing 150 when the module 130 is inserted into the housing 150. The stops 160 and 166 also help align the module 130 with the housing 150.

The module 130 includes four guides, with two guides 190 and 192 being visible. The guides 190 and 192 guide the insertion of the module 130 into the housing 150. The guides 190 and 192 on the side wall 155 are visible and guides on the side wall 156 (behind the module 130 as viewed) are substantially the same. The guides 190 and 192 are each formed as an elongated, linear boss projecting from its surrounding surface 162 of the side wall 155. The guide 190 is disposed between the stop 160 and the end wall 157 and the guide 192 is disposed between the stop 160 and the end wall 158. The guides 190 and 192 extend parallel to the end walls 157 and 158 between the control panel 132 and the bottom 148.

The housing 150 has receivers 194, 196 corresponding to the guides 190 and 192, respectively. The receiver 194 has a throat 198 with a tapered entry 200 for receiving the guide 190. The receiver 194 has a slot 201 that registers with the throat 198 and into which the throat 198 directs the guide 190 to align the module 130 with the housing 150. The receiver 192 similarly has a throat 204 with a tapered entry 206 for receiving the guide 192. The receiver 192 has a slot 208 that registers with the throat 204 and into which the throat 204 directs the guide 192 to align the module 130 with the housing 150.

The side wall 156 has two guides similar to the guides 190 and 192, and as shown in FIG. 4, the housing 150 has two corresponding receivers 193 and 195. The receiver 193 has a throat 199 with a tapered entry 201 for receiving the respective guide on the side wall 156. The receiver 193 has a slot 203 that registers with the throat 199 and into which the throat 199 directs its respective guide to align the module 130 with the housing 150. The receiver 195 similarly has a throat 205 with a tapered entry 207 for receiving its respective guide. The receiver 195 has a slot 209 that registers with the throat 205 and into which the throat 205 directs the respective guide to align the module 130 with the housing 150.

The quick release housing system 102 includes a latch system 220 to latch the module 130 to the housing 150 with a number of latches such as latches 221-224. Each latch 221-224 has a catch 231-234 on the side wall 155 of the module 130. In embodiments, any number of catches may be used. The side wall 156 of the module 130 similarly, has four catches (not visible). Each catch 231-234 projects outward from the side wall 155 and has a ramped side 236 that is disposed at an acute angle 238 (FIG. 7) relative to the side wall 155 and a catch side 239 that is perpendicular to the side wall 155. The catch side 239 faces away from the control panel 232 and in the direction of the bottom 148. As such, the catches 231-234, and the catches on the side wall 156, present a flat surface that is parallel to the bottom 148. In the longitudinal direction 145, the catch 231 is disposed on the side wall 155 between the end wall 157 and the guide 190. The catch 232 is disposed on the side wall 155 between the guide 190 and the stop 160. The catch 233 is disposed on the side wall between the stop 160 and the guide 292. The catch 234 is disposed on the side wall 155 between the guide 192 and the end wall 158. The catches 231-234 are disposed in the transverse direction 149 approximately midway between the control panel 132 and the bottom 148.

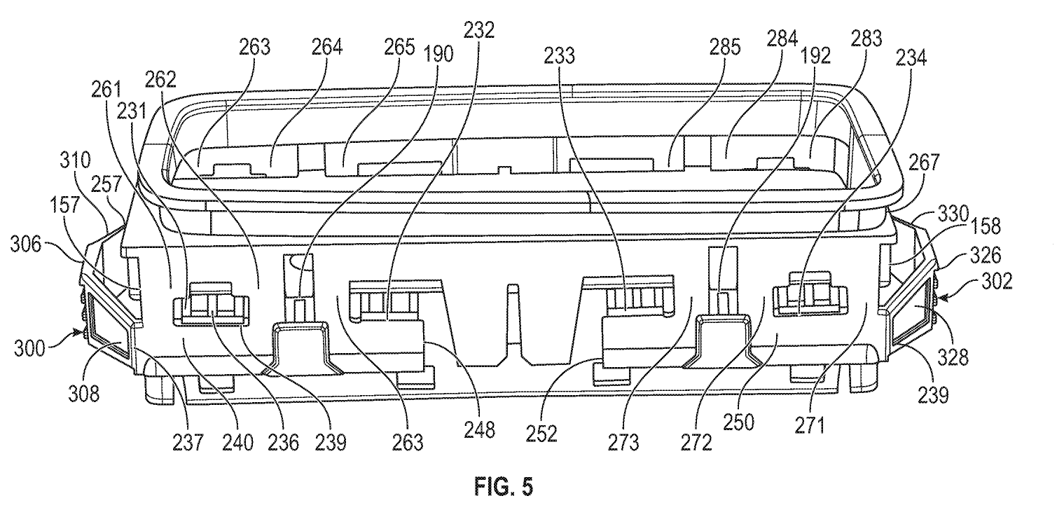

The housing 150 includes features to engage the catches 231-231 (and those on the side wall 156), to securely hold the module 130 in the housing 150. Referring additionally to FIG. 5, on the side of the side wall 155 these features include a latch arm 240 that engages the catches 231 and 232 at their catch sides 239. As additionally shown in FIG. 7, a latch arm 242 engaging a catch 244 on the side wall 156 at its catch side 246. In embodiments, any number of latch arms may be used. As shown in FIGS. 3 and 5, the latch arm 240 extends from an end 237 in the longitudinal direction 145 from the end wall 157 toward the end wall 158 and past both the catches 231 and 232 to a free end 248 that is cantilevered and disposed beyond the catch 232 from the end wall 157. Similarly, a latch arm 250 engages the catches 233 and 234 at their catch sides 239. The latch arm 250 extends from an end 239 in the longitudinal direction 145 toward the end wall 157 from the end wall 158 past both the catches 234 and 233 to a free end 252 that is cantilevered and disposed beyond the catch 233 from the end wall 158. The latch arm 242 is similarly disposed on the side wall 156 side and another latch arm 256 (FIG. 4) is disposed against the side wall 156.

Supports 261-263 extend in the transverse direction 149 and connect the latch arm 240 with the bezel 151. The supports 261-263 are spaced from one another with the support disposed between the end wall 157 and the catch 231, the support 262 disposed between the catch 231 and the guide 190, and the support 263 disposed between the guide 190 and the catch 232. The latch arm 240 is cantilevered on the supports 261-263 from the bezel 151. As shown in FIGS. 4 and 5, the latch arm 256 similarly has three supports 263-265 and is cantilevered from the bezel 151. Each latch arm may have any number of supports, such as one or more.

Supports 271-273 extend in the transverse direction 149 and connect the latch arm 242 with the bezel 151. The supports 271-273 are spaced from one another with the support disposed between the end wall 158 and the catch 234, the support 272 disposed between the catch 234 and the guide 192, and the support 273 disposed between the guide 192 and the catch 233. The latch arm 242 is cantilevered on the supports 271-273 from the bezel 151. As shown in FIGS. 4 and 5, a latch arm 266 similarly has three supports 283-285 and is cantilevered from the bezel 151.

Referring additionally to FIG. 5, an actuator 300 is disposed at the end 237 of the latch arm 240 and at an end 257 of the latch arm 256. In addition, an actuator 302 is disposed at the end 239 of the latch arm 242 and at an end 267 of the latch arm 266. The actuator 300 includes a tab 306, which may also be referred to as a release tab or a push tab. In embodiments, only one actuator 300, 302 may be used. The actuators 300, 302 may have any shape and angles as needed for the application. The tab 306 is a substantially flat piece that is disposed substantially parallel to, and spaced away from, the end wall 157. The tab 306 is suspended in space on links referred to as actuator links 308 and 310. The actuator link 308 is connected with the tab 306 and the latch arm 240 at its end 237 and the actuator link 310 is connected with the tab 306 and the latch arm 256 at its end 257. The tab 306 has no other connections.

The actuator 302 as shown in FIG. 5, is disposed at the end 239 of the latch arm 242 and at the end 257 of the latch arm 256 and at the end 267 of the latch arm 266. The actuator 302 includes a tab 326,which may also be referred to as a release tab or a push tab. The tab 326 is a substantially flat piece that is disposed substantially parallel to, and spaced away from, the end wall 158. The tab 326 is suspended in space on links referred to as actuator links 328 and 330. The actuator link 328 is connected with the tab 326 and the latch arm 242 at its end 239 and the actuator link 330 is connected with the tab 326 and the latch arm 266 at its end 267. The tab 326 has no other connections.

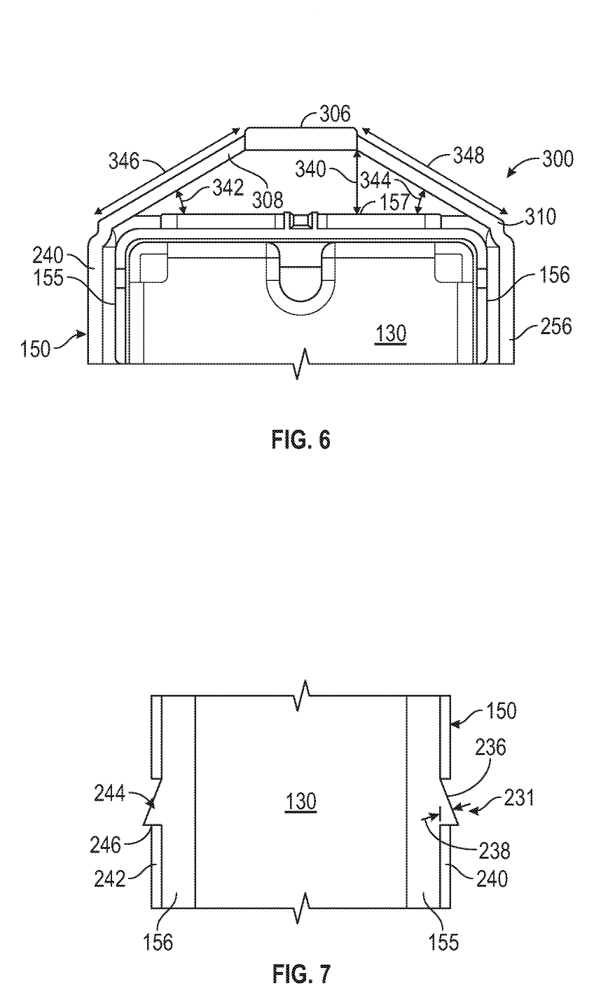

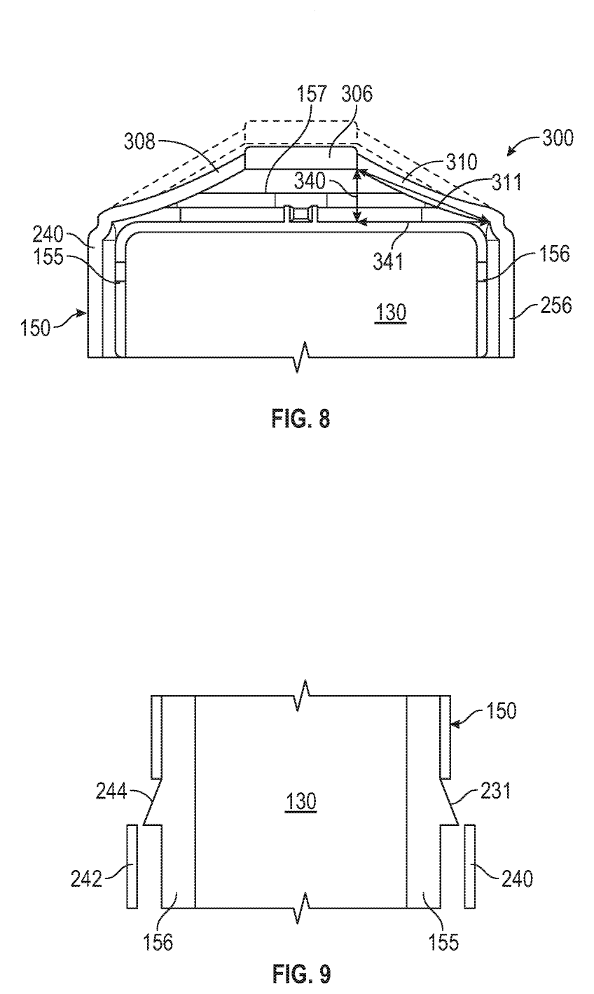

Referring to FIG. 6, the area of the actuator 300 is illustrated with the housing 150 in a latched state on the module 130. The tab 306 is spaced away from the end wall 157 by a distance referred to as travel 340. The travel 340 is the distance that the tab 306 may move toward or away from the end wall 157 when actuated. The actuator link 308 is disposed at an angle 342 relative to the end wall 157 that is acute. The actuator link 310 is disposed at an angle 344 relative to the end wall 157 that is also acute and that may be equal in degrees to the angle 342. The actuator link 308 has a length 346 between the tab 306 and the latch arm 240. The actuator link 310 has a length 348 between the tab 306 and the latch arm 256. The length 346 may be equal in magnitude to the length 348. The travel 340 is set at a maximum travel magnitude such that when actuated, and the tab 306 is moved toward against end wall 157 such that the latch arms 240 and 256 move outward away from their respective side wall 155, 156 as pushed by the actuator links 308, 310, and clear the catches (e.g. catches 231 and 244) as shown in FIGS. 8 and 9, so that the module 130 is free to be removed from the housing 150. Per the Pythagorean theorem, with the actuators links 308 and 310 each as a hypotenuse, depression of the tab 306 and the travel 340 as one side, when the travel 340 is reduced, the side 311 remains the same and the other side 341 must become greater meaning the latch arms 240 and 256 must move outward in the lateral direction 147. At the point of release and unlatching of FIG. 9, additional possible reduction remains in the travel 340 because space exists between the tab 306 and the end wall 157, ensuring release under various conditions.

The guides, such as the guide 190, may as an option, act to inhibit/stop the latch arm 240 from translating in the longitudinal direction 145 so its movement is directed in the lateral direction 147. As seen in FIG. 5, actuation of both actuators 300 and 302 simultaneously by pushing the tabs 306 and 326 toward one another releases the module 130. Conveniently, both tabs 306 and 326 may be moved by one hand of an operator while the module 130 may be pulled free by the operator’s other hand. When the tabs 306 and 326 are released, the actuators 300 and 302 return to their state as shown in FIG. 6.

Accordingly, a quick release housing system for electric modules provides for a convenient way to simultaneously unlatch multiple latches to remove the module. A pair of actuators are opposed and may be simultaneously depressed/actuated. The module may be removed by hand without the need for tools or assistance.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing the exemplary embodiment or exemplary embodiments. It should be understood that various changes can be made in the function and arrangement of elements without departing from the scope of the disclosure as set forth in the appended claims and the legal equivalents thereof.

What is claimed is:

1. A quick release housing system comprising:
an electric module; and
a housing receiving the electric module in a latched state and configured to move to an unlatched state to release the electric module for removal,
wherein the electric module includes a plural number of catches,
wherein the housing includes a number of latch arms that engage the plural number of catches in the latched state,
wherein the housing includes at least one actuator moveable to simultaneously disengage the number of latch arms from the plural number of catches in the unlatched state.

2. The quick release housing system of claim 1, wherein the at least one actuator
includes a tab suspended from the housing by a pair of actuator links so that the tab is moveable toward the electric module to disengage the number of latch arms.

3. The quick release housing system of claim 1, wherein the at least one actuator
comprises two actuators, one at each end of the electric module.

4. The quick release housing system of claim 1, wherein the housing includes a
bezel encircling the electric module, wherein each of the number of latch arms is supported on the bezel in a cantilevered manner.

5. The quick release housing system of claim 1, wherein the electric module has
a guide and the housing has a receiver with a tapered entry for receiving the guide to direct the electric module into the housing.

6. The quick release housing system of claim 1, wherein the electric module has
a stop and the housing has a receiver for receiving the stop to limit movement of the electric module into the housing.

7. The quick release housing system of claim 1, wherein each of the number of
latch arms has a free end and another end connected to the at least one actuator.

8. The quick release housing system of claim 1, comprising a bezel in the
housing, wherein the electric module has a control panel that extends into the bezel and that includes switches.

9. The quick release housing system of claim 1, comprising an armrest, wherein
the electric module is disposed in the armrest.

10. The quick release housing system of claim 1, wherein the housing includes
four latch arms, each latch arm engaged with two catches of the electric module in the latched state.

11. A quick release housing system comprising:
an electric module having a first end and a second end disposed opposite the first end;
a housing receiving the electric module in a latched state and configured to move to an unlatched state to release the electric module for removal,
wherein the electric module includes a plural number of catches,
wherein the housing includes a number of latch arms that engage the plural number of catches in the latched state,
wherein the housing includes a first actuator at the first end of the electric module and a second actuator at the second end of the electric module, wherein the first and the second actuators are moveable to simultaneously disengage the number of latch arms from the plural number of catches in the unlatched state.

12. The quick release housing system of claim 11, wherein the first and second
actuators each includes a tab suspended from the housing by a pair of actuator links so that the tabs are moveable toward the electric module to disengage the number of latch arms.

13. The quick release housing system of claim 11, wherein the first and second
actuators each includes a tab, wherein the tabs are moveable toward one another to move the housing to the unlatched state.

14. The quick release housing system of claim 11, wherein the housing includes a
bezel encircling the electric module, wherein each of the number of latch arms is connected with the bezel by three supports in a cantilevered manner.

15. The quick release housing system of claim 11, wherein the electric module
has a plural number of guides and the housing has a corresponding number of receivers, each with a tapered entry for receiving one of the guides to direct the electric module into the housing.

16. The quick release housing system of claim 11, wherein the electric module
has a stop shaped as an elongated boss projecting from the electric module, and the housing has a receiver for receiving the stop to limit movement of the electric module into the housing.

17. The quick release housing system of claim 11, wherein each of the number of
latch arms has a free end and another end connected to one of the actuators, wherein the housing includes four latch arms, each latch arms engaged with two catches of the electric module in the latched state.

18. The quick release housing system of claim 11, comprising a bezel in the
housing, wherein the electric module has a control panel that extends into the bezel and that includes switches, wherein the electric module is connected in an electrical circuit.

19. The quick release housing system of claim 11, comprising an armrest, wherein
the electric module is disposed in the armrest, wherein the housing has a flange clipped onto the armrest.

20. A quick release housing system for an electrical system of a vehicle, the quick release housing system comprising:
an electric module having a first end and a second end disposed opposite the first end, the electric module having a control panel and a bottom opposite the control panel;
a housing receiving the electric module in a latched state and configured to move to an unlatched state to release the electric module for removal, wherein the housing is connected to the vehicle,
wherein the electric module includes a plural number of catches, each catch having a surface disposed substantially parallel to the bottom and facing the bottom,
wherein the housing includes a number of latch arms that engage the plural number of catches at the surfaces in the latched state,
wherein the housing includes a first actuator at the first end of the electric module and a second actuator at the second end of the electric module, wherein the first and the second actuators are moveable to simultaneously disengage the number of latch arms from the surfaces of the plural number of catches in the unlatched state.
